(19) United States
(12) Patent Application Publication
(10) Pub. No.: US 2004/0149226 A1
(43) Pub. Date: Aug. 5, 2004

(54) Substrate clamp ring with removable contract pads

(75) Inventor: Ming-Chung Chen, Hsin-Chu (TW)

Correspondence Address: TUNG & ASSOCIATES, Suite 120, 838 W. Long Lake Road, Bloomfield Hills, MI, 48302, US

(73) Assignee: Taiwan Semiconductor Manufacturing Co., Ltd.

(21) Appl. No.: 10/356,260

(22) Filed: Jan. 30, 2003

(51) Int. Cl. C23C 16/00; C23F 1/00

(52) U.S. Cl. 118/728

(57) ABSTRACT

A clamp ring having removable contact pads for contacting a substrate during a physical vapor deposition or other semiconductor fabrication process. At least two, and preferably, three or more of the contact pads are removably mounted on the clamp ring in spaced-apart relationship to each other using threaded fasteners or other techniques and provide contact surfaces for the substrate during the process. Prior to recycling of the clamp ring after repeated use thereof, the contact pads may be removed from the clamp ring to prevent recycling-induced damage to the pad contact surfaces on the contact pads. This eliminates or at least minimizes the formation of particle defects at the contact points between the contact pads and the substrate upon resumed use of the contact pads after clamp ring recycling.

### FIELD OF THE INVENTION

The present invention relates to clamp rings for holding semiconductor wafer substrates on a wafer support in a PVD (physical vapor deposition) chamber during the fabrication of integrated circuits on the substrates. More particularly, the present invention relates to a substrate clamp ring that is fitted with removable contact pads which contact the substrate during substrate processing and are removed from the clamp ring during clamp ring cleaning or recycling.

### BACKGROUND OF THE INVENTION

In the fabrication of semiconductor integrated circuits, metal conductor lines are used to interconnect the multiple components in device circuits on a semiconductor wafer. A general process used in the deposition of metal conductor line patterns on semiconductor wafers includes deposition of a conducting layer on the silicon wafer substrate; formation of a photoresist or other mask such as titanium oxide or silicon oxide, in the form of the desired metal conductor line pattern, using standard lithographic techniques; subjecting the wafer substrate to a dry etching process to remove the conducting layer from the areas not covered by the mask, thereby leaving the metal layer in the form of the masked conductor line pattern; and removing the mask layer typically using reactive plasma and chlorine gas, thereby exposing the top surface of the metal conductor lines. Typically, multiple alternating layers of electrically conductive and insulative materials are sequentially deposited on the wafer substrate, and conductive layers at different levels on the wafer may be electrically connected to each other by etching vias, or openings, in the insulative layers and filling the vias using aluminum, tungsten or other metal to establish electrical connection between the conductive layers.

In semiconductor production, the quality of the integrated circuits on the semiconductor wafer is directly correlated with the purity of the fabricating processes, which in turn depends upon the cleanliness of the manufacturing environment. Furthermore, technological advances in recent years in the increasing miniaturization of semiconductor circuits necessitate correspondingly stringent control of impurities and contaminants in the plasma process chamber. When the circuits on a wafer are submicron in size, the smallest quantity of contaminants can significantly reduce the yield of the wafers. For instance, the presence of particles during deposition or etching of thin films can cause voids, dislocations, or short-circuits which adversely affect performance and reliability of the devices constructed with the circuits.

Particle and film contamination has been significantly reduced in the semiconductor industry by improving the quality of clean rooms, by using automated equipment designed to handle semiconductor substrates, and by improving techniques used to clean the substrate surfaces.

Deposition of conductive layers on the wafer substrate can be carried out using any of a variety of techniques. These include oxidation, LPCVD (low-pressure chemical vapor deposition), APCVD (atmospheric-pressure chemical vapor deposition), and PECVD (plasma-enhanced chemical vapor deposition). In general, chemical vapor deposition involves reacting vapor-phase chemicals that contain the required deposition constituents with each other to form a nonvolatile film on the wafer substrate. Chemical vapor deposition is the most widely-used method of depositing films on wafer substrates in the fabrication of integrated circuits on the substrates.

Physical vapor deposition (PVD) is another technique used in the deposition of conductive layers, particularly metal layers, on a substrate. Physical vapor deposition includes techniques such as filament evaporation and electron beam evaporation and, most recently, sputtering. In a sputtering process, high-energy particles strike a solid slab of high-purity target material and physically dislodge atoms from the target. The sputtered atoms are deposited on the substrate.

Major components of a typical PVD process chamber 10, as shown in FIG. 1, include a stainless steel chamber body 12 that is vacuum tight and is equipped with a pump 16 capable of reducing the chamber pressure, a pressure gauge 18, a sputter source or target 20, a power supply (not shown), a wafer holder 14 and a clamp ring 22. The sputter source 20 and the wafer holder 14 are positioned facing each other. The sputter source 20 may be a titanium disc when sputtering of TiN is desired. One of such PVD process chamber is commercially available as Endura.RTM. 5500 from Applied Materials, Inc., of Santa Clara, Calif.

The wafer holder 14 is normally a pedestal of a disc shape. In a top surface of the pedestal 14, metal screws 24 are used as pedestal pins for supporting a wafer 26 at the tips of the screws 24. The pedestal pins 24 allow a gap 25 (FIG. 2) of approximately 1 mm to be maintained between the wafer 26 and the top surface 28 of the pedestal 14. The gap 25 is necessary such that a subsequently deposited film, for instance, a TiN layer, does not glue the wafer to the pedestal surface 28. A thin TiN layer is frequently used on top of an aluminum-copper film layer as an anti-reflective coating for a subsequent lithography process. In a typical PVD deposition process, a plasma cloud 30 is generated by a cascading ionization reaction in which electrons and ion pairs are formed. For instance, when an electron bumps into an argon atom, it forms an argon ion and another electron. The newly formed electron then collides with another argon atom such that a chain reaction or ionization reaction is started. When the electrons bombard the wafer surface, the surface may be charged to a negative voltage higher than 30 volts.

One of the more important components in a sputter chamber is the clamp ring 22, which serves several functions during a sputter process. For instance, one of the functions of the clamp ring 22 is to clamp or secure the wafer 26 to the pedestal 14, typically under the weight of the clamp ring 22. The clamp ring 22 holds the wafer in place on the pedestal when a positive gas pressure is applied between the heater and the pedestal such that heat can be efficiently conducted from the heater to the wafer. Another function served by the clamp ring is to allow a predetermined flow of argon to leak from under the wafer into the sputter chamber. A clamp ring is constructed in a circular shape with an oriented cut-out to match a wafer's flat side. A hood portion 32 is built into the clamp ring 22 for shadowing purposes to protect the lip of the clamp ring 22 from being coated by the sputtered metal particles. A wafer contact surface 34 on the bottom of the clamp ring 22 contacts the upper surface of the wafer 26.

During PVD processing of the wafer 26, intense heat is generated in the clamp ring 22 due to the plasma generated during the process. This can lead to considerable expansion of the clamp ring 22. Accordingly, a coolant port 36 is provided to flow a supply of an inert coolant gas 38, such as argon, to the backside of the wafer 26 to improve thermal transfer between the wafer and the pedestal 14. This takes advantage of the large thermal mass of the pedestal 14 relative to the wafer for conducting temperature. In this way, a predictable and consistent temperature is maintained across the wafer surface during wafer processing, and the various process steps that are used to fabricate devices on the wafer surface may be carried out in a reliable manner.

Throughout repeated use of the clamp ring 22 during sputter processes carried out in the chamber body 12, extraneous metal sputter particles tend to accumulate on the clamp ring 22. Consequently, the clamp ring 22 must be subjected to periodic recycling in order to remove the accumulated metal residue therefrom. However, the recycling process typically involves subjecting the clamp ring 22 to sandblasting techniques and may cause damage to the clamp ring 22, including the wafer contact surface 34, which is constructed in one piece with or fixedly attached to the clamp ring 22. The damaged wafer contact surface 34 has a tendency to induce particle defects into the wafer 26 upon subsequent use of the clamp ring 22. Accordingly, a clamp ring having removable contact pads for contacting the wafer, and which may be removed from the clamp ring during clamp ring recycling, is needed.

It is therefore an object of the present invention to provide removable substrate contact pads for substrate clamp rings.

Another object of the present invention is to provide substrate contact pads which can be easily removed from a substrate clamp ring and replaced, as needed.

Still another object of the present invention is to provide substrate contact pads which can be removed from a substrate clamp ring during recycling of the clamp ring to prevent damage to the contact pads.

Yet another object of the present invention is to provide substrate contact pads which reduce maintenance costs by obviating the need for replacing an entire substrate clamp ring in the event of damage.

Another object of the present invention is to provide a substrate clamp ring with contact clamps which are removably mounted on the substrate clamp ring for contacting a substrate during a physical vapor deposition or other process.

A still further object of the present invention is to provide a method of recycling a substrate clamp ring by removing substrate contact pads from the ring during the recycling and replacing the substrate contact pads on the ring after recycling of the substrate clamp ring.

### SUMMARY OF THE INVENTION

In accordance with these and other objects and advantages, the present invention is generally directed toward a clamp ring having removable contact pads for contacting a substrate during a physical vapor deposition or other semiconductor fabrication process. At least two, and preferably, three or more of the contact pads are removably mounted on the clamp ring in spaced-apart relationship to each other using threaded fasteners or other techniques and provide contact surfaces for the substrate during the process. Prior to recycling of the clamp ring after repeated use thereof, the contact pads may be removed from the clamp ring to prevent recycling-induced damage to the pad contact surfaces on the contact pads. This eliminates or at least minimizes the formation of particle defects at the contact points between the contact pads and the substrate upon resumed use of the contact pads after clamp ring recycling. The removable feature of the contact pads facilitates replacement of the contact pads on the clamp ring, as needed in cases of damage or wear, for example, without the need for replacing the entire clamp ring.

### BRIEF DESCRIPTION OF THE DRAWINGS

The invention will now be described, by way of example, with reference to the accompanying drawings, in which:

FIG. 1 is a schematic view of a typical conventional physical vapor deposition (PVD) chamber during wafer processing;

FIG. 2 is a cross-sectional view of a typical conventional clamp ring for clamping a substrate to a pedestal in a PVD chamber;

FIG. 3 is a bottom view of a substrate clamp ring with removable contact pads in implementation of the present invention;

FIG. 3A is a cross-sectional view, taken along section lines 3A-3A in FIG. 3, of a contact pad, removably mounted on the substrate clamp ring;

FIG. 4 is a top view, partially in section, of a contact pad removably mounted on the bottom surface of the substrate clamp ring in accordance with the present invention;

FIG. 5 is a cross-sectional view, taken along section lines 5-5 in FIG. 4, of a substrate clamp ring with removable contact pads in accordance with the present invention, with one of the contact pads engaging a substrate; and

FIG. 6 is a front view of a contact pad mounted on the bottom surface of the substrate clamp ring (partially in section) in accordance with the present invention.

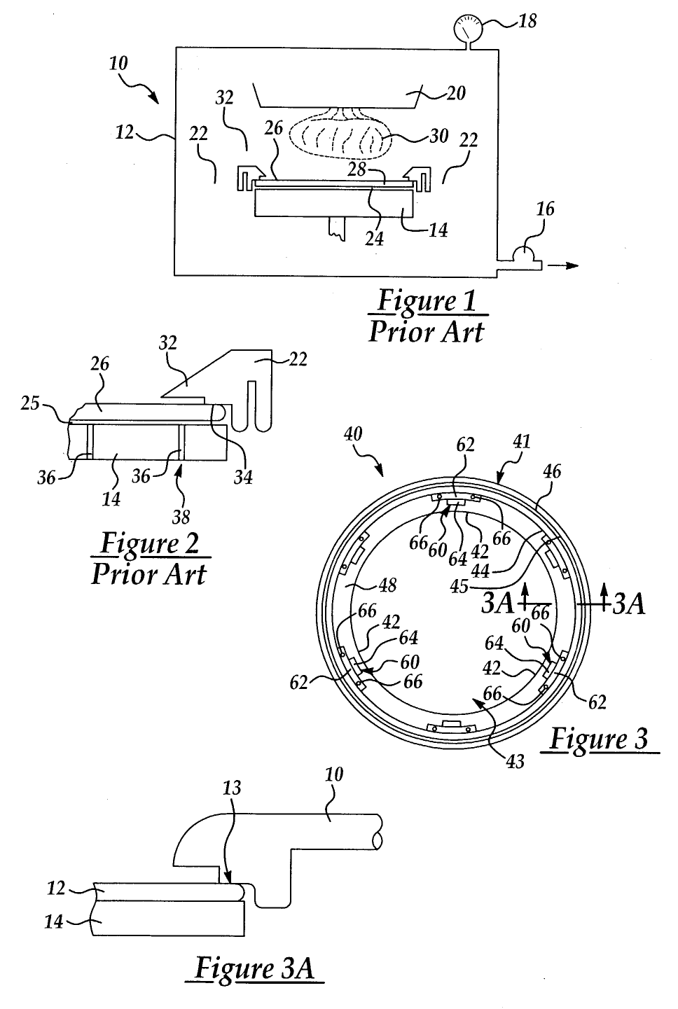

### DESCRIPTION OF THE PREFERRED EMBODIMENTS

The present invention has particularly beneficial utility in the clamping of a semiconductor wafer substrate onto a substrate support during the fabrication of integrated circuits on the substrate, particularly during a physical vapor deposition (PVD) process, for example. However, the invention is not so limited in application, and while references may be made to such semiconductor wafer substrate and physical vapor deposition process, the invention is more generally applicable to securing a substrate on a substrate support in a variety of other industrial and mechanical applications.

The substrate clamp ring with removable contact pads of the present invention is designed to facilitate contact of the substrate clamp ring with the substrate at the contact pads. In a preferred embodiment, the substrate clamp ring includes at least two of the contact pads removably mounted on the substrate clamp ring in substantially diametrically-opposed relationship with each other. The contact pads may be individually removed from the substrate clamp ring and recycled or replaced, as needed, apart from the substrate clamp ring. When it becomes necessary to recycle the substrate clamp ring such as, for example, after repeated use in order to remove metal particles formed thereon during PVD processes, the contact pads can be removed from the substrate clamp ring in order to prevent damage to the substrate-contacting surfaces on the contact pads and replaced on the substrate clamp ring after recycling of the substrate clamp ring. Furthermore, the damaged or worn contact pads can be individually removed from and replaced with new contact pads on the substrate clamp ring, as needed, without the need for replacing the entire substrate clamp ring.

Referring initially to FIGS. 3-6, an illustrative embodiment of a substrate clamp ring 40 in accordance with the present invention includes an annular ring body 41 that defines a central opening 43. The ring body 41 typically includes an inner, annular hood portion 42 with a flat ring bottom 48. An outer circumferential ridge 46 and an inner circumferential ridge 44, separated by a groove 45, may protrude from the ring bottom 48. In use, the groove 45 receives a ring mounting element (not shown) inside a process chamber (not shown) for proper positioning and mounting of the clamp ring 40 inside the process chamber. However, it is understood that the present invention is applicable to a variety of substrate clamp rings having alternative configurations and is not limited to use with the substrate clamp ring 40 having the particular features shown and described herein.

As shown in FIG. 3, at least two, and typically three, four or more contact pads 60 are removably mounted, in equally-spaced relationship to each other, on the ring bottom 48 of the substrate clamp ring 40 in the manner hereinafter described. Each contact pad 60 is constructed of a material which is process compatible, i.e., resistant to the harsh conditions that are found within the processing environment, and may include any of various suitable ceramic materials, for example. The material should be durable and have a low thermal coefficient of expansion and low thermal conductivity. For example, each contact pad 60 can be made using a process-compatible alumina material which does not etch and is easy to clean. Other suitable materials include aluminum nitride and calcium carbonate, in non-exclusive particular.

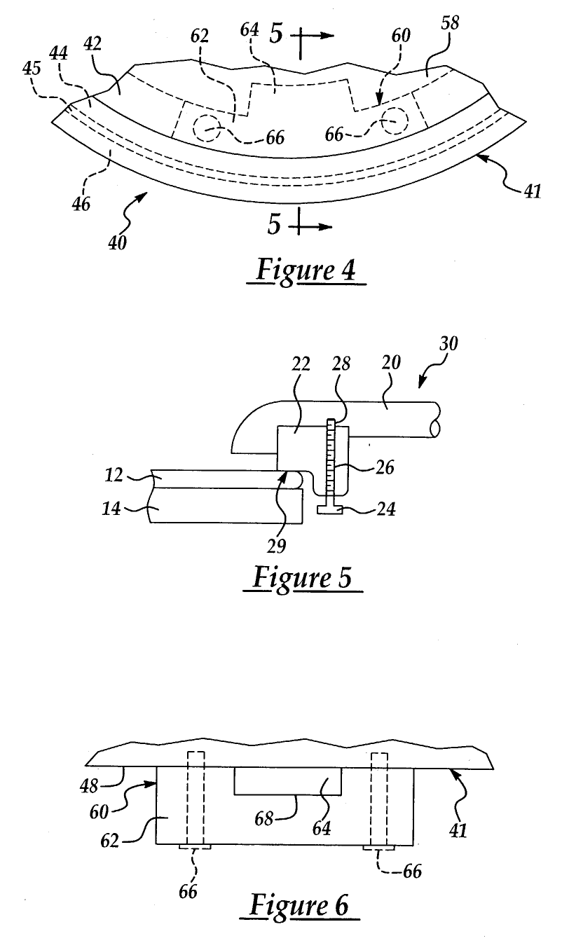

Each contact pad 60 typically includes an elongated pad base 62, the longitudinal dimension of which substantially matches the curvature of the substrate clamp ring 40 to which the contact pad 60 is mounted, as shown in FIG. 4. A contact tab 64, having a substantially flat bottom substrate contact surface 68, as shown in FIGS. 3A and 6, extends generally perpendicularly from the pad base 62. As further shown in FIG. 6, each contact pad 60 is removably mounted on the ring bottom 48 of the substrate clamp ring 40 typically by extending a pair of threaded fasteners 66 through respective fastener openings (not shown), provided in the pad base 62, and threading the fasteners 66 into respective fastener openings (not shown) provided in the ring bottom 48. As shown in FIG. 3A, the pad base 62 typically extends along the inner surface of the inner ridge 44 of the ring body 41, with the upper surface of the contact tab 64 secured flat against the ring bottom 48.

Referring next to FIG. 5, in application of the substrate clamp ring 40, the contact pads 60 are removably mounted on the ring bottom 48 of the ring body 41, typically using the threaded fasteners 66, in the manner heretofore described. Next, the substrate 58 is placed on a substrate support 52 inside a process chamber (not shown), such as a PVD chamber, for example. The substrate clamp ring 40 is then used to hold or secure the substrate 58 on the substrate support 52, with the bottom substrate contact surface 68 of each contact tab 64 on each contact pad 60 engaging the upper surface of the substrate 58, at the edge of the substrate 58. Clamp support elements (not shown) may be inserted into the annular groove 45 between the inner circumferential ridge 44 and the outer circumferential ridge 46 of the ring body 41, to properly support and position the substrate clamp ring 40 in the process chamber, in conventional fashion. Accordingly, with the substrate 58 typically bearing the weight of the substrate clamp ring 40 at the respective contact pads 60, a gap 50 is defined between the upper surface of the substrate 58 and the ring bottom 48 of the ring body 41.

During the PVD or other process, the substrate clamp ring 40 holds the substrate 58 in place on the substrate support 52 such that heat can be efficiently and uniformly conducted to the substrate 58. Furthermore, the substrate clamp ring 40 allows a predetermined flow of argon to leak from under the substrate 58 into the process chamber. The angled hood portion 42 enables most of the sputtered metal particles to reflect off of the substrate clamp ring 40 and preventing the sputtered metal particles from prematurely coating the substrate clamp ring 40. Intense heat is generated in the substrate clamp ring 40 due to the plasma generated in the process chamber during the process. Accordingly, a supply of an inert coolant gas 56 such as argon may be flowed to the backside of the substrate 58 through each of multiple coolant ports 54 extending through the substrate support 52, typically in conventional fashion, to improve thermal transfer between the substrate 58 and the substrate support 52. This takes advantage of the large thermal mass of the pedestal 14 relative to the wafer for conducting temperature. In this way, a predictable and consistent temperature is maintained across the surface of the substrate 58 during processing, and the various process steps that are used to fabricate devices on the substrate surface may be carried out in a reliable manner.

Throughout repeated use of the substrate clamp ring 40 during sputter or other processes carried out in the process chamber, extraneous metal sputter particles or other contaminating by-products of the processes tend to accumulate on the substrate clamp ring 40, despite the reflecting action of the hood portion 42. Consequently, the substrate clamp ring 40 must be subjected to periodic recycling or cleaning in order to remove the accumulated metal or other residue therefrom. The recycling process typically involves subjecting the ring body 41 to sandblasting techniques which dislodge the metal particles therefrom and would otherwise have a tendency to damage the substrate contact surface 68 on each of the contact pads 60, if the contact pads 60 remained in place on the substrate clamp ring 40 during recycling. Accordingly, prior to recycling of the substrate clamp ring 40, each of the contact pads 60 is removed from the ring body 41 of the substrate clamp ring 40 by unthreading the threaded fasteners 66 from the ring body 41 and the contact pad 60. In this manner, the substrate clamp ring 40 and the contact pads 60 may be recycled or cleaned separately from each other, thereby avoiding damage to the contact pads 60. After the substrate clamp ring 40 is recycled, the separately-cleaned or recycled contact pads 60 may be replaced on the ring body 41 typically using the threaded fasteners 66. Alternatively, a replacement set of the contact pads 60 may be removably secured on the ring body 41 prior to resuming use of the substrate clamp ring 40. Consequently, the damage-free recycled, cleaned or replacement contact pads 60 have little or no tendency to induce particle defects on the substrate 58 upon resumption of use of the substrate clamp ring 40.

While the preferred embodiments of the invention have been described above, it will be recognized and understood that various modifications can be made in the invention and the appended claims are intended to cover all such modifications which may fall within the spirit and scope of the invention.

What is claimed is:

1. A substrate clamp ring for holding a substrate on a substrate support, comprising:
a ring body; and
at least two spaced-apart contact pads removably carried by said ring body for contacting the substrate.

2. The substrate clamp ring of claim 1 wherein each of said contact pads comprises a pad base removably carried by said ring body and a contact tab carried by said pad base for contacting the substrate.

3. The substrate clamp ring of claim 1 wherein each of said contact pads comprises a ceramic material.

4. The substrate clamp ring of claim 3 wherein each of said contact pads comprises a pad base removably carried by said ring body and a contact tab carried by said pad base for contacting the substrate.

5. The substrate clamp ring of claim 1 further comprising at least one threaded fastener removably engaging each of said contact pads and said ring body for removably mounting each of said contact pads on said ring body.

6. The substrate clamp ring of claim 5 wherein each of said contact pads comprises a pad base removably carried by said ring body and a contact tab carried by said pad base for contacting the substrate, and wherein said at least one threaded fastener extends through said pad base.

7. The substrate clamp ring of claim 5 wherein each of said contact pads comprises a ceramic material.

8. The substrate clamp ring of claim 7 wherein each of said contact pads comprises a pad base removably carried by said ring body and a contact tab carried by said pad base for contacting the substrate, and wherein said at least one threaded fastener extends through said pad base.

9. The substrate clamp ring of claim 1 wherein said at least two spaced-apart contact pads comprises at least three spaced-apart contact pads.

10. The substrate clamp ring of claim 9 wherein each of said contact pads comprises a pad base removably carried by said ring body and a contact tab carried by said pad base for contacting the substrate.

11. The substrate clamp ring of claim 9 wherein each of said contact pads comprises a ceramic material.

12. The substrate clamp ring of claim 9 further comprising at least one threaded fastener removably engaging each of said contact pads and said ring body for removably mounting each of said contact pads on said ring body.

13. A substrate clamp ring for holding a substrate on a substrate support, comprising:
a ring body; and
a plurality of spaced-apart contact pads each comprising a pad base removably engaging said ring body and a contact tab extending generally perpendicularly from said pad base for contacting the substrate.

14. The substrate clamp ring of claim 13 wherein each of said contact pads comprises a ceramic material.

15. The substrate clamp ring of claim 13 further comprising at least one threaded fastener extending through said pad base of each of said contact pads and removably engaging said ring body for removably mounting said each of said contact pads on said ring body.

16. The substrate clamp ring of claim 15 wherein said at least one threaded fastener comprises a pair of spaced-apart threaded fasteners.

17. A method of recycling a clamp ring comprising a ring body and at least two spaced-apart contact pads removably carried by said ring body for contacting a substrate, comprising the steps of:
removing said contact pads from said ring body; and
recycling said ring body separately from said contact pads.

18. The method of claim 17 further comprising the step of recycling said contact pads and replacing said contact pads on said ring body.

19. The method of claim 17 wherein said contact pads comprise a first set of contact pads and further comprising the step of providing a second set of at least two spaced-apart contact pads on said ring body after said recycling said ring body separately from said contact pads.

20. The method of claim 17 wherein said at least two spaced-apart contact pads comprises at least three spaced-apart contact pads.
